(19) United States
(12) Patent Application Publication
(10) Pub. No.: US 2025/0014970 A1
(43) Pub. Date: Jan. 9, 2025

(54) METHOD FOR PRODUCING A PACKAGE FOR A SEMICONDUCTOR CHIP, PACKAGE FOR A SEMICONDUCTOR CHIP AND SEMICONDUCTOR DEVICE

(71) Applicant: AMS-OSRAM INTERNATIONAL GMBH, Regensburg (DE)

(72) Inventors: Mazwan Mansor, Pendang (MY); Ismail Ithnain, Pendang (MY); Mohd Fauzi Zainordin, Pendang (MY)

(21) Appl. No.: 18/708,553

(22) PCT Filed: Nov. 12, 2021
(86) PCT No.: PCT/EP2021/081523

§ 371 Date: May 8, 2024

(51) Int. Cl. H01L 23/495; H01L 21/48

(52) U.S. Cl. CPC H01L 23/49558; H01L 21/4839; H01L 21/4842

(57) ABSTRACT

In an embodiment a method for producing a package includes providing a carrier layer comprising an electrically conductive material, forming at least one first recess at a first side of the carrier layer, filling the first recess with a first molding compound, depositing a cover layer comprising an electrically conductive material on the first molding compound, forming at least one second recess at a second side of the carrier layer, wherein the second recess extends up to the first molding compound arranged in the first recess, the second side of the carrier layer facing away from the first side, filling the second recess with a second molding compound, forming at least one third recess in the cover layer, wherein the third recess extends up to the first molding compound arranged in the first recess, and filling the third recess with a third molding compound.

### CROSS-REFERENCE TO RELATED APPLICATIONS

This patent application is a national phase filing under section 371 of PCT/EP2021/081523, filed Nov. 12, 2021, which is incorporated herein by reference in its entirety.

### TECHNICAL FIELD

A method for producing a package for a semiconductor chip, a package for a semiconductor chip and a semiconductor device are provided.

### BACKGROUND

Semiconductor chips are usually arranged in a package to protect the chips from damages. As semiconductor chip are employed in a wide range of applications, it is necessary to produce a large number of them and thus also a large number of packages.

### SUMMARY

Embodiments provide a method for producing a package for a semiconductor chip in an efficient way. Further embodiments provide a package for a semiconductor chip that can be produced in an efficient way. Yet other embodiments provide a semiconductor device that can be produced in an efficient way.

According to at least one embodiment of the method for producing a package for a semiconductor chip, the method comprises the step of providing a carrier layer comprising an electrically conductive material. The carrier layer can be or comprise a substrate. The carrier layer can have a main plane of extension. The carrier layer can comprise Cu or a Cu alloy.

According to at least one embodiment of the method, the method comprises forming at least one first recess at a first side of the carrier layer. The first recess can be formed by etching. The first recess can be formed by etching the carrier layer in a region at the first side. The first recess extends partially through the carrier layer. This means, the first recess does not extend through the whole carrier layer. The first recess can have the shape of a cuboid. In a cross section through the carrier layer the first recess can have the shape of a rectangle, wherein the cross section extends in a plane that extends perpendicular to the main plane of extension of the carrier layer. The first recess can have a larger extension in a lateral direction that extends parallel to the main plane of extension of the carrier layer than in a vertical direction that extends perpendicular to the main plane of extension of the carrier layer. It is also possible that at least two or a plurality of first recesses are formed. The first recesses can all have the same features. The first recesses can be arranged spaced apart from each other.

According to at least one embodiment of the method, the method comprises filling the first recess with a first molding compound. The first molding compound can comprise an electrically insulating material. The first molding compound can comprise a resin. The resin can be liquid when it is filled in the first recess. The first recess is completely filled with the first molding compound.

According to at least one embodiment of the method, the method comprises depositing a cover layer comprising an electrically conductive material on the first molding compound. The cover layer can be deposited directly on the first molding compound. The cover layer can be deposited by sputtering. The cover layer can comprise Cu or a Cu alloy. The cover layer can be deposited at the first side of the carrier layer. The cover layer can extend over the whole extension of the carrier layer. Thus, the cover layer can completely cover the carrier layer at the first side.

According to at least one embodiment of the method, the method comprises forming at least one second recess at a second side of the carrier layer, wherein the second recess extends up to the first molding compound arranged in the first recess and the second side of the carrier layer faces away from the first side. Before the second recess is formed, the carrier layer with the cover layer is flipped. This means, the carrier layer with the cover layer is rotated by 180°. Before the rotation, the first side faces up and after the rotation, the second side faces up. The second recess can be formed by etching. The second recess can be formed by etching the carrier layer in a region at the second side. The second recess extends partially through the carrier layer. This means, the second recess does not extend through the whole carrier layer. The second recess can have the shape of a cuboid. It is also possible that at least two or a plurality of second recesses are formed. The second recesses can all have the same features. The second recesses can be arranged spaced apart from each other. That the second recess extends up to the first molding compound arranged in the first recess can mean that the second recess is in direct contact with the first molding compound. Thus, the first recess and the second recess together form one recess within the carrier layer. The first recess and the second recess together extend completely through the carrier layer.

According to at least one embodiment of the method, the method comprises filling the second recess with a second molding compound. The second molding compound can comprise an electrically insulating material. The second molding compound can comprise a resin. The resin can be liquid when it is filled in the second recess. The second recess is completely filled with the second molding compound. The second molding compound can be in direct contact with the first molding compound.

According to at least one embodiment of the method, the method comprises forming at least one third recess in the cover layer, wherein the third recess extends up to the first molding compound arranged in the first recess. Before the third recess is formed, the carrier layer with the cover layer is flipped. After flipping, the cover layer faces up. The third recess can be formed by etching. The third recess can be formed by etching the cover layer partially, this means in a region. The third recess extends completely through the cover layer. This means, the third recess extends through the whole cover layer. The third recess can have the shape of a cuboid. It is also possible that at least two or a plurality of third recesses are formed. The third recesses can all have the same features. The third recesses can be arranged spaced apart from each other. That the third recess extends up to the first molding compound arranged in the first recess can mean that the third recess is in direct contact with the first molding compound. Thus, the first recess, the second recess and the third recess together form one recess within the carrier layer and the cover layer.

According to at least one embodiment of the method, the method comprises filling the third recess with a third molding compound. The third molding compound can comprise an electrically insulating material. The third molding compound can comprise a resin. The resin can be liquid when it is filled in the third recess. The third recess is completely filled with the third molding compound. The third molding compound can be in direct contact with the first molding compound.

According to at least one embodiment of the method, the first recess has a larger extent along a lateral direction that extends parallel to the main plane of extension of the carrier layer than the second recess and the third recess. This means, the first recess has a larger extent along the lateral direction than the second recess and the first recess has a larger extent along the lateral direction than the third recess. The second recess can have the same extent along the lateral direction as the third recess.

According to at least one embodiment of the method, the method comprises providing a carrier layer comprising an electrically conductive material, forming at least one first recess at a first side of the carrier layer, filling the first recess with a first molding compound, depositing a cover layer comprising an electrically conductive material on the first molding compound, forming at least one second recess at a second side of the carrier layer, wherein the second recess extends up to the first molding compound arranged in the first recess and the second side of the carrier layer faces away from the first side, filling the second recess with a second molding compound, forming at least one third recess in the cover layer, wherein the third recess extends up to the first molding compound arranged in the first recess, and filling the third recess with a third molding compound, wherein the first recess has a larger extent along a lateral direction that extends parallel to the main plane of extension of the carrier layer than the second recess and the third recess.

The method described herein has the advantage that no tie bar is required for the package. Instead, the molding compounds hold the package together. Thus, burr-shaped structures in or on the package are advantageously avoided. In addition, as no tie bar is required the setup is simplified which is why the package can be produced in easier way. This means, the package can be produced efficiently.

Furthermore, the molding compounds in the recesses form a structure which reduces or prevents the seepage of material from a surface of the package into the package. The surface of the package is arranged at the second side of the carrier layer. As the first recess has a larger extent along the lateral direction than the second recess a structure is formed within the carrier layer where the structure has a smaller extent along the lateral direction close to the second side and a larger extent at the first side. The shape of this structure is given in a cross-section through the carrier layer where the cross-section extends in a plane that extends perpendicular to the main plane of extension of the carrier layer. Because of the larger extent of the first recess in comparison to the second recess the path for material leaking into the interface between the second molding compound and the carrier layer is increased. This path does not only extent along the second molding compound but also along the first molding compound. Because of the larger extent of the first recess with the first molding compound the length of this path is increased in comparison to a package without the first recess. This reduces or prevents the seepage of material at this interface from the second side.

Two electrical contacts of a semiconductor chip arranged in or on the package can be electrically connected with two contact areas at the second side and arranged at opposite sides adjacent to the second molding compound. These two contact areas are electrically insulated from each other by the second molding compound. Thus, the two electrical contacts of the semiconductor chip can be arranged close to each other. This allows the semiconductor chip to be relatively small. Consequently, a larger number of semiconductor chips can be arranged within the package than for the case that the semiconductor chips are larger. Furthermore, for the case that the semiconductor chips are relatively small, the remaining area at the second side of the carrier layer is larger. On this remaining area a layer comprising a metal can be applied so that a reflective layer is formed. Increasing the area of the reflective layer has the advantage that the brightness of a device with the package and an optoelectronic semiconductor chip is increased. The setup of the package also enables that the electrical connections between the semiconductor chip and the two contact areas at the second side can have a relatively large volume. This is achieved by arranging the electrical contacts close to each other where the second molding compound electrically insulates the two contact areas of the carrier layer that are electrically contacted. In this way, the thermal dissipation is improved. Moreover, a mechanically stable connection can be formed.

Overall, the method is easy to carry out as the carrier layer is flipped at least three times during the process so that the different molding compounds can easily be filled in the respective recesses from a side facing up. Additionally, the method enables a cheap production of the package. For example, for the three molding compounds the same material can be employed which reduces the costs.

According to at least one embodiment of the method, the carrier layer with the cover layer, the first molding compound, the second molding compound and the third molding compound forms a carrier of the package. This means, that on these components forming the carrier of the package a semiconductor chip can be arranged. On the carrier also a sidewall of the package can be arranged. The sidewall can surround a region where a semiconductor chip can be arranged. Thus, with the method a package for a semiconductor chip can be formed. The package can be a quad flat no-leads (QFN) package. The semiconductor chip can be a flip chip.

According to at least one embodiment of the method, the carrier layer and the cover layer comprise the same material. The carrier layer and the cover layer can comprise the same electrically conductive material. The carrier layer and the cover layer can consist of the same material. The carrier layer and the cover layer together thus form a layer within which the three recesses extend. Thus, the path for material leaking into the interface between the carrier layer and the molding compounds is also increased by the shape of the first recess and the third recess. As the first recess also has a larger extent than the third recess, the path of the interface between the carrier layer with the cover layer and the molding compounds is further increased by the extent of the first recess along the interface between the cover layer and the first recess. Increasing the length of this path has the advantage that seepage of material in the carrier layer from the second side is reduced or avoided.

According to at least one embodiment of the method, the first molding compound, the second molding compound and the third molding compound comprise the same material. The first molding compound, the second molding compound and the third molding compound can comprise the same resin. The first molding compound, the second molding compound and the third molding compound can consist of the same material. Filling the three recesses with the same material has the advantage that only one type of molding compound is required. This simplifies the production method.

According to at least one embodiment of the method, the second recess extends up to the center of the first recess, where the center of the first recess is given in a plane that extends parallel to the main plane of extension of the carrier layer. The second recess can extend from the second side along a direction that extends perpendicular to the vertical direction. The second recess extends up to the position where the center of the first recess is arranged. The center of the first recess is a geometrical center. The first recess and the second recess are the arranged in such a way that within a cross section through the carrier layer in a plane that extends perpendicular to the main plane of extension of the carrier layer, a symmetry axis runs through the first recess and the second recess along the vertical direction. Thus, in this cross-section the first recess and the second recess together form the shape of a “T”. With this shape of the first recess and the second recess the path for material leaking into the carrier layer is increased.

According to at least one embodiment of the method, the third recess extends up to the center of the first recess, where the center of the first recess is given in a plane that extends parallel to the main plane of extension of the carrier layer. The third recess can extend from the side of the cover layer facing away from the carrier layer along a direction that extends perpendicular to the vertical direction. The third recess extends up to the position where the center of the first recess is arranged. The first recess and the third recess are the arranged in such a way that within a cross section through the carrier layer and the cover layer in a plane that extends perpendicular to the main plane of extension of the carrier layer, a symmetry axis runs through the first recess and the third recess along the vertical direction. Thus, in this cross-section the first recess and the third recess together form the shape of a “T”. With this shape of the first recess and the third recess the path for material leaking into the carrier layer is increased.

According to at least one embodiment of the method, the second recess and the third recess extend along the same direction. The second recess and the third recess can extend along a direction that extends parallel to the vertical direction. The first recess, the second recess and the third recess can be arranged in such a way that within a cross section through the carrier layer and the cover layer in a plane that extends perpendicular to the main plane of extension of the carrier layer a symmetry axis runs through the first recess, the second recess and the third recess along the vertical direction. With this shape of the recesses the path for material leaking into the carrier layer is increased.

According to at least one embodiment of the method, the second recess is filled with the second molding compound from the second side of the carrier layer and the second molding compound is deposited on the carrier layer at the second side at least in places. This can mean, that during the filling of the second recess with the second molding compound, the second side of the carrier layer faces up. The second molding compound can be deposited on the whole carrier layer at the second side. This means, the second molding compound can cover the whole carrier layer at the second side after the deposition of the second molding compound. Thus, the carrier layer can be completely covered with the second molding compound at the second side. Thus, no mask is required for depositing the second molding compound. Furthermore, it is possible to fill several recesses within the carrier layer at the second side with the second molding compound in one step.

According to at least one embodiment of the method, the second molding compound arranged on the carrier layer is removed in places after forming and filling the third recess. The remaining parts of the second molding compound on the carrier layer form at least two insulating structures. The two insulating structures can be arranged spaced apart from each other. Along a lateral direction the two insulating structures can be arranged at opposite sides of the second recess. The insulating structures can advantageously be employed for electrically insulating parts of the semiconductor chip that are no electrical contacts from the carrier layer.

According to at least one embodiment of the method, an elevation layer is deposited on the carrier layer at the second side on an area adjacent to the second recess after removing the second molding compound in places from the carrier layer. The elevation layer is deposited on an area at the second side which is free of the second molding compound. Thus, the elevation layer can be in direct contact with the carrier layer. The elevation layer can be arranged on an area that is arranged between one of the insulation structures and the second recess. It is also possible that the elevation layer is deposited on two areas. Each of these two areas is arranged between one of the insulation structures and the second recess. The elevation layer can comprise an electrically conductive material. The elevation layer can comprise the same material as the carrier layer. The elevation layer can consist of the same material as the carrier layer. The two elevation layers each form an area on which an electrical contact of a semiconductor chip can be arranged or to which an electrical contact of a semiconductor chip can be electrically connected.

According to at least one embodiment of the method, a reflecting layer is deposited on the elevation layer and in places on the carrier layer at the second side. The reflecting layer can completely cover the elevation layer. It is also possible that the reflecting layer is deposited on both elevation layers. The reflecting layer can completely cover both elevation layers. Furthermore, the reflecting layer can be deposited on the areas at the second side of the carrier layer that are not covered by insulating structures. The reflecting layer can comprise a metal. The reflecting layer can comprise titanium dioxide. Thus, the reflecting layer can have a high reflectivity. The reflectivity of the reflecting layer comprising titanium dioxide is increased by arranging the reflecting layer on the elevation layer comprising an electrically conductive material instead of on one of the molding compounds. This has the advantage that electromagnetic radiation emitted by a semiconductor chip arranged on the package can be reflected away from the package which increases the brightness.

According to at least one embodiment of the method, a fourth recess is formed in the second molding compound deposited on the carrier layer and the fourth recess has a larger extent along the lateral direction than the first recess. The fourth recess can be arranged above the three other recesses and the insulating structures. After forming the fourth recess the second molding compound arranged on the carrier layer can have the shape of sidewalls that surround the second recess and the insulating structures. The sidewalls can be sidewalls of the package. Thus, the sidewalls can be arranged at edges of the package. The sidewalls can completely surround an inner region where at least one semiconductor chip can be arranged. Thus, sidewalls of the package can be formed in a simple and efficient way from the second molding compound.

Furthermore, a package for a semiconductor chip is provided. The package can preferably be produced by the method for producing a package for a semiconductor chip described herein. This means all features disclosed for the method for producing a package for a semiconductor chip are also disclosed for the package for a semiconductor chip and vice-versa.

According to at least one embodiment of the package for a semiconductor chip, the package comprises a carrier layer comprising an electrically conductive material, wherein the carrier layer has a first side and a second side facing away from the first side.

According to at least one embodiment of the package for a semiconductor chip, the package comprises a first recess in the carrier layer at the first side of the carrier layer. This can mean that the first recess extends within the carrier layer from the first side.

According to at least one embodiment of the package for a semiconductor chip, the package comprises a second recess in the carrier layer that extends from the second side up to the first recess.

According to at least one embodiment of the package for a semiconductor chip, the package comprises a cover layer arranged at the first side on the first recess, wherein the cover layer comprises an electrically conductive material. This means, the cover layer covers the first recess. It is also possible that the cover layer covers the carrier layer at the first side.

According to at least one embodiment of the package for a semiconductor chip, the package comprises a third recess in the cover layer, wherein the third recess extends up to the first recess. The third recess extends completely through the cover layer.

According to at least one embodiment of the package for a semiconductor chip, the first recess is filled with a first molding compound. The first recess can be completely filled with the first molding compound.

According to at least one embodiment of the package for a semiconductor chip, the second recess is filled with a second molding compound. The second recess can be completely filled with the second molding compound.

According to at least one embodiment of the package for a semiconductor chip, the third recess is filled with a third molding compound. The third recess can be completely filled with the third molding compound.

According to at least one embodiment of the package for a semiconductor chip, the first recess has a larger extent along a lateral direction that extends parallel to the main plane of extension of the carrier layer than the second recess and the third recess. Thus, the first molding compound has a larger extent along the lateral direction than the second molding compound and the third molding compound.

According to at least one embodiment of the package for a semiconductor chip, the package comprises a carrier layer comprising an electrically conductive material, wherein the carrier layer has a first side and a second side facing away from the first side, a first recess in the carrier layer at the first side of the carrier layer, a second recess in the carrier layer that extends from the second side up to the first recess, a cover layer arranged at the first side on the first recess, wherein the cover layer comprises an electrically conductive material, and a third recess in the cover layer, wherein the third recess extends up to the first recess, wherein the first recess is filled with a first molding compound, the second recess is filled with a second molding compound, the third recess is filled with a third molding compound, and the first recess has a larger extent along a lateral direction that extends parallel to the main plane of extension of the carrier layer than the second recess and the third recess.

The package has the advantage that it can be produced in an efficient way by the method described herein. Furthermore, the seepage of material from the second side into the carrier layer is reduced or prevented. Because of the larger extent of the first recess in comparison to the second recess the path for material leaking into the interface between the second molding compound and the carrier layer is increased. The setup of the package also enables that electrical connections between a semiconductor chip and two contact areas at the second side can have a relatively large volume. This is achieved by arranging the electrical contacts close to each other where the second molding compound electrically insulates the two contact areas of the carrier layer that are electrically contacted. In this way, the thermal dissipation is improved. Moreover, a mechanically stable connection can be formed.

According to at least one embodiment of the package for a semiconductor chip, an elevation layer is arranged on the carrier layer at the second side on an area adjacent to the second recess. The elevation layer can be arranged on an area at the second side which is free of the second molding compound. Thus, the elevation layer can be in direct contact with the carrier layer. It is also possible that the elevation layer is arranged on two areas. Each of these two areas is arranged between one of the insulation structures and the second recess. The two elevation layers each form an area on which an electrical contact of a semiconductor chip can be arranged or to which an electrical contact of a semiconductor chip can be electrically connected.

Furthermore, a semiconductor device is provided. The semiconductor device comprises the package for a semiconductor chip. This means all features disclosed for the package for a semiconductor chip are also disclosed for the semiconductor device and vice-versa.

According to at least one embodiment of the semiconductor device, the semiconductor device comprises the package and a semiconductor chip that is arranged within the package. The semiconductor chip can be an optoelectronic semiconductor chip. The semiconductor chip can be a flip chip. The semiconductor chip can be fixed to the package. The semiconductor chip can be arranged at the second side.

According to at least one embodiment of the semiconductor device, the semiconductor device comprises the package and a plurality of semiconductor chips that are arranged within the package. The semiconductor chips can each be an optoelectronic semiconductor chip. The semiconductor chips can each be a flip chip. The semiconductor chips can each be fixed to the package. The semiconductor chips can each be arranged at the second side.

According to at least one embodiment of the semiconductor device, the semiconductor chip comprises a first electrical contact and a second electrical contact at its side facing the carrier layer and the first electrical contact is electrically connected with the carrier layer at the second side and at a side of the second recess that is arranged opposite to a side of the second recess at which the second electrical contact is electrically connected with the carrier layer at the second side. In a cross-section through the semiconductor device in a plane which extends perpendicular to the main plane of extension of the carrier layer, the carrier layer comprises two contact areas. The two contact areas are arranged at the second side. The two contact areas are arranged at opposite sides of the second recess. Thus, the two contact areas are electrically insulated from each other via the second molding compound arranged in the second recess. The contact areas are a first contact area and a second contact area. The first contact area is electrically connected with the first electrical contact and the second contact area is electrically connected with the second electrical contact. The electrical contacts can be connected with the respective contact area by soldering. The two electrical contacts can advantageously be arranged close to each other as the two contact areas are electrically insulated from each other via the second molding compound. Furthermore, the connection between the electrical contacts and the respective contact area can have a volume that is large enough to allow a good thermal dissipation and a mechanically stable connection.

### BRIEF DESCRIPTION OF THE DRAWINGS

The following description of figures may further illustrate and explain exemplary embodiments. Components that are functionally identical or have an identical effect are denoted by identical references. Identical or effectively identical components might be described only with respect to the figures where they occur first. Their description is not necessarily repeated in successive figures.

FIGS. 1-13 show an exemplary embodiment of the method for producing a package for a semiconductor chip;

FIG. 14 shows an exemplary embodiment of the package for a semiconductor chip;

FIGS. 15-17 show further exemplary embodiments of the method for producing a package for a semiconductor chip;

FIG. 18 shows another exemplary embodiment of the package for a semiconductor chip;

FIGS. 19-21 show yet further exemplary embodiments of the method for producing a package for a semiconductor chip;

FIGS. 22 and 23 show further exemplary embodiments of the package for a semiconductor chip;

FIG. 24 shows an exemplary embodiment of the semiconductor device;

FIG. 25 shows a step of a further exemplary embodiment of the method for producing a package for a semiconductor chip; and

FIG. 26 shows another exemplary embodiment of the semiconductor device.

### DETAILED DESCRIPTION OF ILLUSTRATIVE EMBODIMENTS

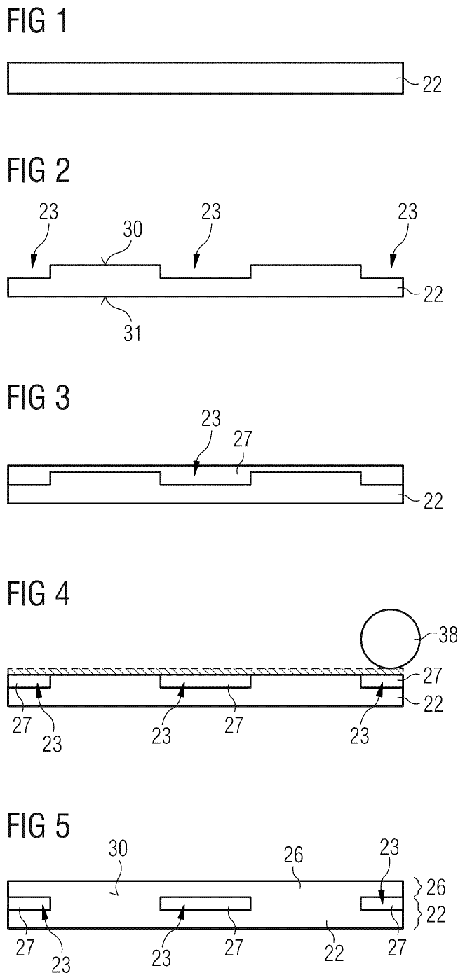

With FIGS. 1 to 13 an exemplary embodiment of the method for producing a package 20 for a semiconductor chip 21 is described. FIG. 1 shows that in a first step of the method a carrier layer 22 is provided. The carrier layer 22 comprises an electrically conductive material. FIG. 1 shows a cross section through the carrier layer 22.

FIG. 2 shows that in a next step of the method a first recess 23 is formed at a first side 30 of the carrier layer 22 in the carrier layer 22. As the package 20 can be designed to have space for a plurality of semiconductor chips 21, some steps of the method are carried out for a plurality of positions or components. In the method a plurality of first recesses 23 is formed. In FIG. 2 as an example one first recess 23 is shown in the center and parts of two other first recesses 23 are shown at the sides. It is however possible that more first recesses 23 than shown in FIG. 2 are formed. The first recesses 23 are formed by etching the carrier layer 22 in places at the first side 30. A second side 31 of the carrier layer 22 faces away from the first side 30.

As shown in FIG. 3, in a next step of the method the first recesses 23 are filled with a first molding compound 27. The first molding compound 27 can comprise an epoxy molding compound. The first molding compound 27 is filled in the liquid state into the first recesses 23. The first molding compound 27 can be filled in the first recesses 23 by employing a stencil mask or by employing a squeegee method.

As shown in FIG. 4, in a next step of the method a part of the first molding compound 27 is removed by grinding. For this purpose a grinding tool 38 is moved over the first molding compound 27. The grinding tool 38 can be a diamond roller. The removing can be carried out in two or three grinding steps with different roughness levels. The first molding compound 27 is removed up to the first recesses 23. This means, the first molding compound 27 that is not arranged within one of the first recesses 23 is removed.

As shown in FIG. 5, in a next step of the method a cover layer 26 is deposited on the first molding compound 27 and on the carrier layer 22 at the first side 30. The cover layer 26 comprises an electrically conductive material. The cover layer 26 can be deposited by sputtering. As the cover layer 26 can comprise the same material as the carrier layer 22, in FIG. 5 no border is depicted between the cover layer 26 and the carrier layer 22. The cover layer 26 completely covers the first molding compound 27 in the first recesses 23 and the carrier layer 22 at the first side 30.

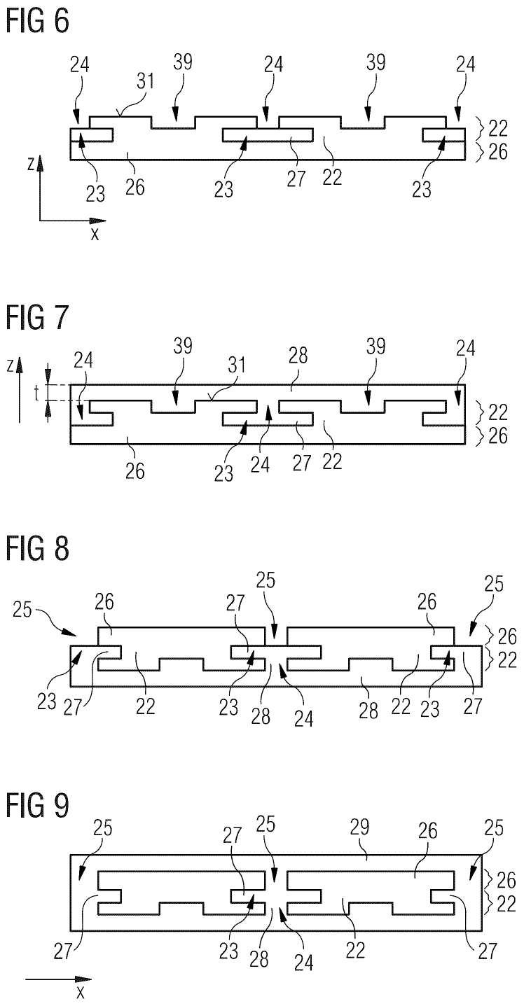

As shown in FIGS. 6, in a next step of the method a second recess 24 is formed at the second side 31 of the carrier layer 22 in the carrier layer 22. Before the second recess 24 is formed the carrier layer 22 with the cover layer 26 is flipped. After flipping, the second side 31 faces up. The second recess 24 extends up to the first molding compound 27 arranged in the first recess 23. As described with respect to the first recess 23, it is also possible to form a plurality of second recesses 24. As an example in FIG. 6 one second recess 24 is shown in the center and two second recesses 24 are partially shown at the sides. Furthermore, two further recesses 39 are formed at the second side 31 of the carrier layer 22 in the carrier layer 22. Each further recess 39 is arranged between two second recesses 24 along a lateral direction x which extends perpendicular to the main plane of extension of the carrier layer 22. The further recesses 39 each have the same extent along a vertical direction z as the second recesses 24. The vertical direction z extends perpendicular to the lateral direction x. The further recesses 39 each have a larger extent along the lateral direction x than the second recesses 24. The second recesses 24 and the further recesses 39 are formed by etching. The first recesses 23 each have a larger extent along the lateral direction x than the second recesses 24. The second recesses 24 each extend up to the center of the adjacent first recess 23, where the center of the first recess 23 is given in a plane that extends parallel to the main plane of extension of the carrier layer 22.

As shown in FIG. 7, in a next step of the method the second recesses 24 and the further recesses 39 are filled with a second molding compound 28. The second molding compound 28 can comprise an epoxy molding compound. The filling with the second molding compound 28 can be carried out as described for the first molding compound 27. As the first molding compound 27 and the second molding compound 28 can comprise the same material, no border is shown between the first molding compound 27 and the second molding compound 28. Furthermore, the whole second side 31 of the carrier layer 22 is covered with the second molding compound 28. The thickness of the second molding compound 28 on the carrier layer 22 at the second side 31 depends on whether the second molding compound 28 is employed to form side walls of the package 20 in a later step of the method or not. If the second molding compound 28 arranged on the carrier layer 22 is employed to form side walls of the package 20 in a later step of the method, the thickness of the second molding compound 28 on the carrier layer 22 is larger than shown in FIG. 7.

As shown in FIG. 8, in a next step of the method a third recess 25 is formed in the cover layer 26. Before forming the third recess 25 the carrier layer 22 with the cover layer 26 is flipped. After flipping, the cover layer 26 faces up. A plurality of third recesses 25 can be formed. As an example, one third recess 25 is shown in the center of FIG. 8 and parts of two third recesses 25 are shown at the sides of FIG. 8. The third recesses 25 extend completely through the cover layer 26. The third recesses 25 are formed by etching. The third recesses 25 each extend up to the first molding compound 27 arranged in the first recess 23 that is arranged adjacent to the respective third recess 25. The third recesses 25 each extend up to the center of the adjacent first recess 23, where the center of the first recess 23 is given in a plane that extends parallel to the main plane of extension of the carrier layer 22.

As shown in FIG. 9, in a next step of the method the third recesses 25 are filled with a third molding compound 29. The third molding compound 29 can comprise an epoxy molding compound. The filling with the third molding compound 29 can be carried out as described for the first molding compound 27. The third recesses 25 are completely filled with the third molding compound 29 and the cover layer 26 is completely covered by the third molding compound 29. As the third molding compound 29 can comprise the same material as the first molding compound 27, no border is drawn between the first molding compound 27 and the third molding compound 29. The first recesses 23 each have a larger extent along the lateral direction x than the second recesses 24 and third recesses 25. The second recesses 24 and the third recesses 25 have the same extent along the lateral direction x.

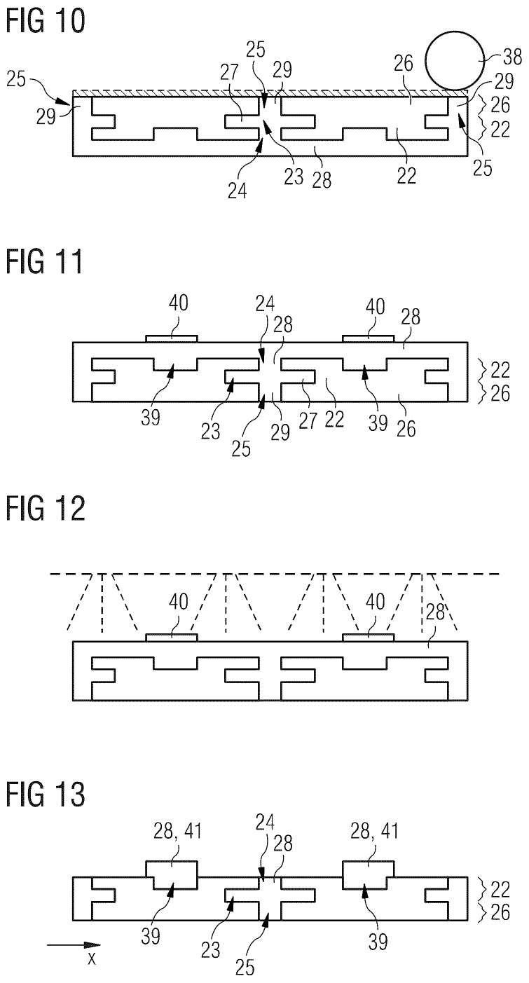

As shown in FIG. 10, in a next step of the method the third molding compound 29 is partially removed by grinding. For this purpose a grinding tool 38 is moved over the third molding compound 29. The grinding tool 38 can be a diamond roller. The removing can be carried out in two or three grinding steps with different roughness levels. The third molding compound 29 is removed up to the third recesses 25. This means, the third molding compound 29 that is not arranged within one of the third recesses 25 is removed. After removing the third molding compound 29 the cover layer 26 is exposed.

As shown in FIG. 11, in a next step of the method the carrier layer 22 with the cover layer 26 and the molding compounds 27, 28, 29 is flipped. The second molding compound 28 faces up after flipping. Above the further recesses 39 and areas adjoining the further recesses 39 masks 40 are arranged. Thus, above each further recess 39 one mask 40 is arranged. Each mask can have the shape of an “L”. It is also possible that each mask 40 has another shape. The shape of each mask 40 can be different from an “L”, for example each mask 40 can have the shape of a rectangle or a circle.

As shown in FIG. 12, in a next step of the method the second molding compound 28 with the masks 40 is irradiated with electromagnetic radiation.

As shown in FIG. 13, in a next step of the method in a photolithography step the parts of the second molding compound 28 that were irradiated and not covered by a mask 40 are removed. Thus, regions of the second molding compound 28 remain above the further recesses 39 and adjacent to the further recesses 39. Each region of the second molding compound 28 that remains above one of the further recesses 39 is referred to as an insulating structure 41. Along the lateral direction x of the first recess 23, the second recess 24 and the third recess 25 are arranged between two insulating structures 41. The second molding compound 28 within the second recess 24 is not removed.

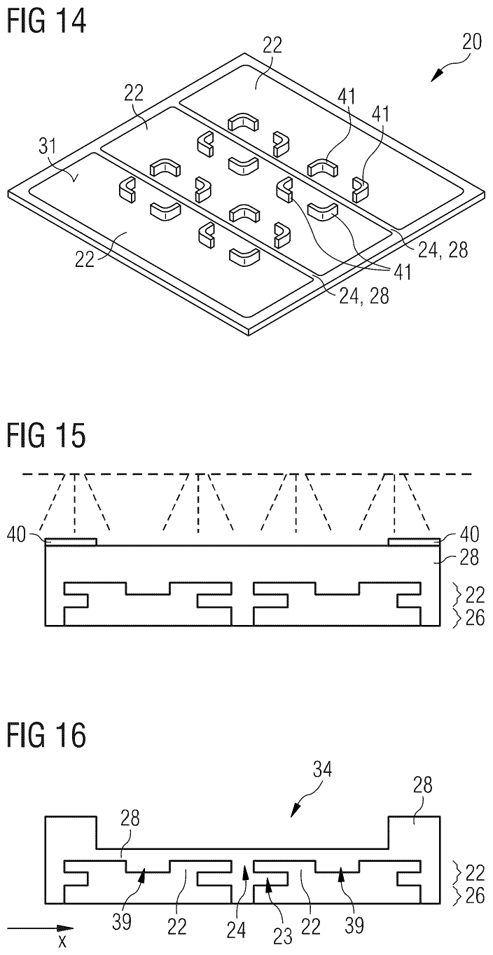

FIG. 14 shows an exemplary embodiment of the package 20 for a semiconductor chip 21. FIG. 14 shows a perspective view on the structure shown in FIG. 13. At the second side 31 of the carrier layer 22 several insulating structures 41 are arranged. Two second recesses 24 extend over the whole extent of the package 20. Advantageously, no tie bars are required between the three regions separated from each other by the second recesses 24. The carrier layer 22 with the cover layer 26, the first molding compound 27, the second molding compound 28 and the third molding compound 29 forms a carrier of the package 20.

FIG. 15 shows a step of another exemplary embodiment of the method. Instead of the step shown in FIG. 11, the step of FIG. 15 is carried out. Furthermore, for the embodiment shown in FIG. 15 the second molding compound 28 is deposited with a larger thickness in the step shown in FIG. 7 than depicted in FIG. 7. In FIG. 15 to masks 40 are arranged on the second molding compound 28. The two masks 40 are arranged at opposite sides of the second molding compound 28. It is also possible that only one mask 40 is employed which has the shape of a frame that surrounds the second molding compound 28 from all sides. After arranging the mask 40, the second molding compound 28 with the mask 40 is irradiated with electromagnetic radiation.

As shown in FIG. 16, in a next step of the method in a photolithography step the parts of the second molding compound 28 that were irradiated and not covered by a mask 40 are removed. Thus, a frame of the second molding compound 28 remains at the sides. Furthermore, a layer of the second molding compound 28 remains on the carrier layer 22, the further recesses 39 and the second recess 24. Thus, a fourth recess 34 is formed in the second molding compound 28 deposited on the carrier layer 22 and the fourth recess 34 has a larger extent along the lateral direction x than the first recess 23.

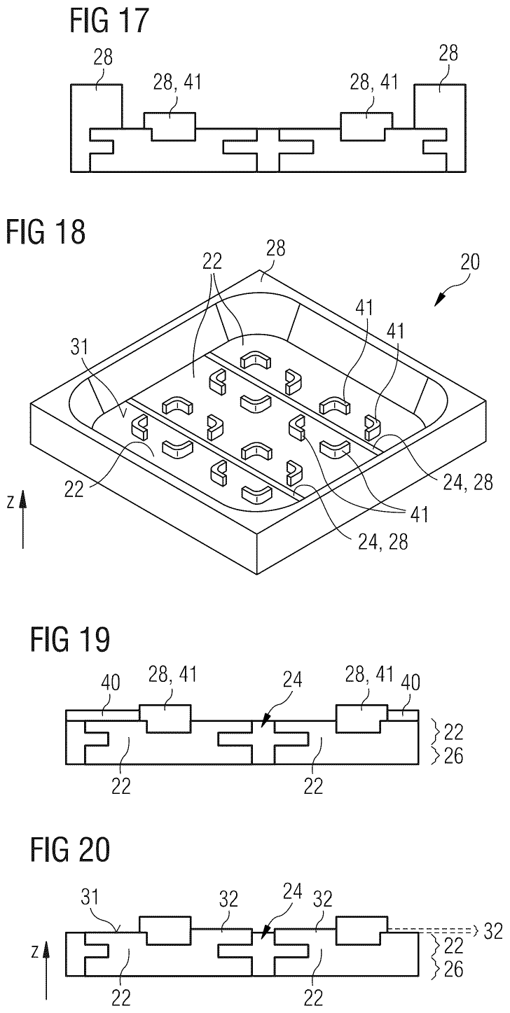

As shown in FIG. 17, in a next step of the method the insulating structures 41 are formed in the same way as described with FIGS. 11, 12 and 13.

FIG. 18 shows an exemplary embodiment of the package 20 for a semiconductor chip 21. FIG. 18 shows a perspective view on the structure shown in FIG. 17. At the second side 31 of the carrier layer 22 several insulating structures 41 are arranged. Two second recesses 24 extend over the whole extent of the package 20. The second molding compound 28 is arranged as a frame surrounding the area where the insulating structures 41 are arranged. Thus, the second molding compound 28 forms the sidewalls of the package 20. The sidewalls project above the insulating structures 41 and the carrier layer 22 in the vertical direction z. The carrier layer 22 with the cover layer 26, the first molding compound 27, the second molding compound 28 and the third molding compound 29 forms a carrier of the package 20.

With FIGS. 19, 20 and 21 steps of a further exemplary embodiment of the method for producing a package 20 for a semiconductor chip 21 are described. FIG. 19 shows a step which is carried out after the step shown in FIG. 13. It is also possible to carry out the steps shown in FIGS. 19 to 21 after the step shown in FIG. 17. FIG. 19 shows, that two masks 40 are applied on the carrier layer 22. The masks 40 are applied on areas that are not arranged between an insulating structure 41 and the second recess 24. Thus, the masks 40 are applied on areas adjacent to the insulating structures 41 at sides facing away from the second recess 24.

As shown in FIG. 20, in a next step of the method an elevation layer 32 is deposited on the carrier layer 22 on the areas that are not covered by any mask 40. The elevation layer 32 is deposited on the carrier layer 22 at the second side 31 on an area adjacent to the second recess 24. During the deposition of the elevation layer 32, the masks 40 are still arranged on the carrier layer 22. The elevation layer 32 can be deposited by sputtering. The elevation layer 32 can comprise copper. As the elevation layer 32 can comprise the same material as the carrier layer 22, no border is drawn between the carrier layer 22 and the elevation layer 32. The thickness in vertical direction z of the elevation layer 32 is relatively small. Thus, it is visible in FIG. 20 that the regions with the elevation layer 32 are slightly elevated in comparison to the same regions in FIG. 19. The elevation layer 32 is arranged on the areas that are arranged between an insulating structure 41 and the second recess 24. This means, the elevation layer 32 is arranged on the carrier layer 22 at the second side 31 on an area adjacent to the second recess 24.

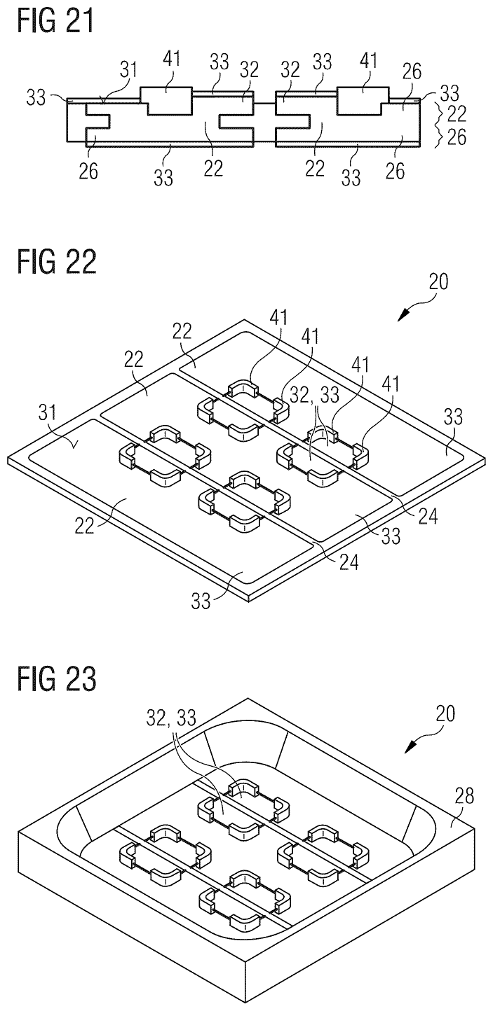

As shown in FIG. 21, in a next step of the method a reflecting layer 33 is deposited. The reflecting layer 33 is deposited on the elevation layer 32 and in places on the carrier layer 22 at the second side 31. The reflecting layer 33 is deposited on the areas of the carrier layer 22 at the second side 31 that are not covered by an insulating structure 41. Furthermore, the reflecting layer 33 is deposited on the cover layer 26 at the side facing away from the carrier layer 22.

FIG. 22 shows an exemplary embodiment of the package 20 for a semiconductor chip 21. FIG. 22 shows a perspective view on the structure shown in FIG. 21. At the second side 31 of the carrier layer 22 several insulating structures 41 are arranged. Two second recesses 24 extend over the whole extent of the package 20. The area of the carrier layer 22 that is not covered by an insulating structure 41 is covered with the reflecting layer 33. The reflecting layer 33 is also arranged on the elevation layer 32. Except for the elevation layer 32 and the reflecting layer 33 the embodiment shown in FIG. 22 has the same setup as shown in FIG. 14.

FIG. 23 shows an exemplary embodiment of the package 20 for a semiconductor chip 21. FIG. 23 shows a perspective view on the structure shown in FIG. 21 with sidewalls as shown in FIGS. 17 and 18. Except for the sidewalls, the package 20 shown in FIG. 23 has the same setup as the package 20 shown in FIG. 22.

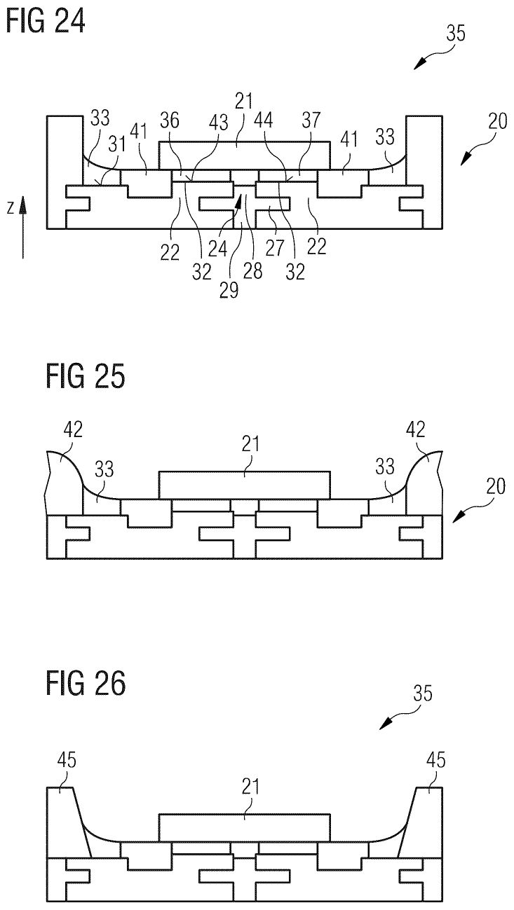

FIG. 24 shows a cross-section through an exemplary embodiment of a semiconductor device 35. The semiconductor device 35 comprises the package 20 shown in FIG. 23 and a semiconductor chip 21 that is arranged within the package 20. The sidewalls of the package 20 project over the semiconductor chip 21 in the vertical direction z. The semiconductor chip 21 comprises a first electrical contact 36 and a second electrical contact 37 at its side facing the carrier layer 22. The first electrical contact 36 is electrically connected with the carrier layer 22 at the second side 31 and at a side of the second recess 24 that is arranged opposite to a side of the second recess 24 at which the second electrical contact 37 is electrically connected with the carrier layer 22 at the second side 31. This means, the package 20 can comprise two contact areas 43, 44. A first contact area 43 can be formed by the elevation layer 32 arranged between one of the insulating structures 41 and the second recess 24. The second contact area 44 can be formed by the elevation layer 32 arranged between the other one of the insulating structures 41 and the second recess 24. The first electrical contact 36 of the semiconductor chip 21 is electrically connected with the first contact area 43 and thus also with the carrier layer 22 as the elevation layer 32 comprises an electrically conductive material. The second electrical contact 37 of the semiconductor chip 35 is electrically connected with the second contact area 44 and thus also with the carrier layer 22 as the elevation layer 32 comprises an electrically conductive material. The package 20 has the advantage that material leaking into the interface between the second molding compound 28 and the carrier layer 22 and into the interface between the first molding compound 27 and the carrier layer 22 has a long path along the second molding compound 28 and the first molding compound 27 for leaking far into the package 20. Thus, because of this path seepage of material at this interface is reduced or prevented. Seepage of the material of the reflecting layer 33 as for example titanium dioxide or seepage of other materials is reduced or prevented. As the region of the carrier layer 22 that is electrically connected with the first electrical contact 36 is electrically insulated from the region of the carrier layer 22 that is electrically connected with the second electrical contact 37 via the first molding compound 27, the second molding compound 28 and the third molding compound 29, the first electrical contact 36 and the second electrical contact 37 can be arranged relatively close to each other. This enables to reduce the size of the semiconductor chip 21 which allows to arrange more semiconductor chips 21 within the package 20. On the regions of the carrier layer 22 at the second side 31 that are not covered by an insulating structure 41 or by a semiconductor chip 21, the reflecting layer 33 is arranged. Thus, the area on which the reflecting layer 33 is arranged, can be maximized which increases the brightness for the case that the semiconductor chip 21 is an optoelectronic semiconductor chip 21.

With FIG. 25 a step of a further exemplary embodiment of the method for producing a package 20 for a semiconductor chip 21 is described. With the step shown in FIG. 25 an exemplary embodiment of the semiconductor device 35 is formed. A semiconductor chip 21 is arranged on the package 20 shown in FIG. 22 in the same way as described with FIG. 24. In a next step the reflecting layer 33 is deposited. In order to prevent that material of the reflecting layer 33 drops from the surface of the package 20 a protective structure 42 in the shape of a frame is arranged on the package 20 before depositing the reflecting layer 33. The protective structure 42 can be a dam for the reflecting layer 33.

FIG. 26 shows another exemplary embodiment of the semiconductor device 35. A semiconductor chip 21 is arranged on the package 20 shown in FIG. 22 in the same way as described with FIG. 24. The semiconductor device 35 has the same set up as the embodiment shown in FIG. 24 except for a frame 45 that forms the sidewalls in FIG. 26 instead of the second molding compound 28 as it is shown in FIG. 24. The frame 45 can comprise a molding compound, for example an epoxy molding compound.

It will be appreciated that the disclosure is not limited to the disclosed embodiments and to what has been particularly shown and described hereinabove. Rather, features recited in separate dependent claims or in the description may advantageously be combined. Furthermore, the scope of the disclosure includes those variations and modifications, which will be apparent to those skilled in the art. The term “comprising”, insofar it was used in the claims or in the description, does not exclude other elements or steps of a corresponding feature or procedure. In case that the terms “a” or “an” were used in conjunction with features, they do not exclude a plurality of such features. Moreover, any reference signs in the claims should not be construed as limiting the scope.

1.-15. (canceled)

16. A method for producing a package for a semiconductor chip, the method comprising:
providing a carrier layer comprising an electrically conductive material;
forming at least one first recess at a first side of the carrier layer;
filling the first recess with a first molding compound;
depositing a cover layer comprising an electrically conductive material on the first molding compound;
forming at least one second recess at a second side of the carrier layer, wherein the second recess extends up to the first molding compound arranged in the first recess, the second side of the carrier layer facing away from the first side;
filling the second recess with a second molding compound;
forming at least one third recess in the cover layer, wherein the third recess extends up to the first molding compound arranged in the first recess; and
filling the third recess with a third molding compound,
wherein the first recess has a larger extent along a lateral direction that extends parallel to a main plane of extension of the carrier layer than the second recess and the third recess.

17. The method according to claim 16, wherein the carrier layer with the cover layer, the first molding compound, the second molding compound and the third molding compound forms a carrier of the package.

18. The method according to claim 16, wherein the carrier layer and the cover layer comprise the same material.

19. The method according to claim 16, wherein the first molding compound, the second molding compound and the third molding compound comprise the same material.

20. The method according to claim 16, wherein the second recess extends up to a center of the first recess, and wherein the center of the first recess is in a plane that extends parallel to the main plane of extension of the carrier layer.

21. The method according to claim 16, wherein the third recess extends up to a center of the first recess, where the center of the first recess is given in a plane that extends parallel to the main plane of extension of the carrier layer.

22. The method according to claim 16, wherein the second recess is filled with the second molding compound from the second side of the carrier layer, and wherein the second molding compound is deposited on the carrier layer at the second side at least in places.

23. The method according claim 22, further comprising removing in places the second molding compound arranged on the carrier layer after forming and filling the third recess.

24. The method according claim 23, further comprising depositing an elevation layer on the carrier layer at the second side on an area adjacent to the second recess after removing the second molding compound in the places from the carrier layer.

25. The method according to claim 24, further comprising depositing a reflecting layer on the elevation layer and in places on the carrier layer at the second side.

26. The method according to claim 22, further comprising forming a fourth recess in the second molding compound deposited on the carrier layer, wherein the fourth recess has a larger extent along the lateral direction than the first recess.

27. A package for a semiconductor chip, the package comprising:
a carrier layer comprising an electrically conductive material, wherein the carrier layer has a first side and a second side facing away from the first side;
a first recess in the carrier layer at the first side of the carrier layer;
a second recess in the carrier layer that extends from the second side up to the first recess;
a cover layer arranged at the first side on the first recess, wherein the cover layer comprises an electrically conductive material;
a third recess in the cover layer,
wherein the third recess extends up to the first recess,
wherein the first recess is filled with a first molding compound,
wherein the second recess is filled with a second molding compound,
wherein the third recess is filled with a third molding compound,
wherein the first recess has a larger extent along a lateral direction that extends parallel to the main plane of extension of the carrier layer than the second recess and the third recess; and
an elevation layer arranged on the carrier layer at the second side on an area adjacent to the second recess.

28. A semiconductor device comprising:
the package according to claim 27; and
the semiconductor chip arranged within the package.

29. The semiconductor device according to claim 28, wherein the semiconductor chip comprises a first electrical contact and a second electrical contact at its side facing the carrier layer and the first electrical contact is electrically connected with the carrier layer at the second side and at a side of the second recess that is arranged opposite to a side of the second recess at which the second electrical contact is electrically connected with the carrier layer at the second side.
